(19) United States
(12) Patent Application Publication
(10) Pub. No.: US 2014/0151892 A1
(43) Pub. Date: Jun. 5, 2014

(54) THREE DIMENSIONAL THROUGH-SILICON VIA CONSTRUCTION

(71) Applicant: NVIDIA CORPORATION, Santa Clara, CA (US)

(72) Inventors: Teckgyu Kang, San Jose, CA (US); Abraham F. Yee, Cupertino, CA (US)

(73) Assignee: NVIDIA CORPORATION, Santa Clara, CA (US)

(21) Appl. No.: 13/690,364

(22) Filed: Nov. 30, 2012

(51) Int. Cl. H01L 23/498

(52) U.S. Cl. CPC H01L 23/49827
USPC 257/774

(57) ABSTRACT

Embodiments of the present invention include devices having multiple dies packaged together in the same package. The multiple dies are disposed on an interposer which is then disposed on a package substrate. The interposer includes a semiconductor substrate, such as silicon, having vias extending from a front surface of the interposer to a back surface of the interposer. The interposer may be a passive interposer or an active poser. An active interposer includes the functionality of one or more dies and thus reduces the number of dies disposed on the active interposer.

### BACKGROUND OF THE INVENTION

1. Field of the Invention

Embodiments of the present invention generally relate to packaging of electronic components and, more specifically, to three-dimensional through-silicon via constructions.

2. Description of the Related Art

A die in the context of integrated circuits is a small block of semiconducting material on which a given functional circuit is fabricated. The dies are packaged, for example, by coupling to a packaging substrate, and then positioned on a printed circuit board to interconnect the dies. However, interconnecting dies in this manner limits the electrical performance of a device because of the long electrical paths required for communication between dies (e.g., electric current must travel from a first die through the printed circuit board to a second die). Additionally, the individual packaging of dies requires a relatively large area of printed circuit board to accommodate all of the packed devices utilized in an electronic device. The relatively large area of printed circuit board limits the minimum physical size of the device. Furthermore, the individually packaged dies are each assembled in different package types, thus increasing cost and complexity of forming the assembled device.

As the foregoing illustrates, what is needed in the art is a new device package.

### SUMMARY OF THE INVENTION

One embodiment of the invention includes an electronic device having a package substrate, an interposer disposed on and electrically coupled to the package substrate, and a plurality of dies disposed on and electrically coupled to the interposer.

Benefits of the present invention include a smaller form factor for manufactured devices. Because multiple dies with different functions are integrated into a single package, the amount of space required to interconnect the dies is reduced as compared to discretely packaged dies. Additionally, because the device has a smaller form factor, the electrical performance of the device is increased due to shorter electrical paths between the dies.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a sectional view of a device, according to one embodiment of the invention.

FIGS. 2A-2F illustrate multiple dies positioned on passive interposers, according to embodiments of the invention.

FIGS. 3A-3F illustrate multiple dies positioned on active interposers, according to embodiments of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

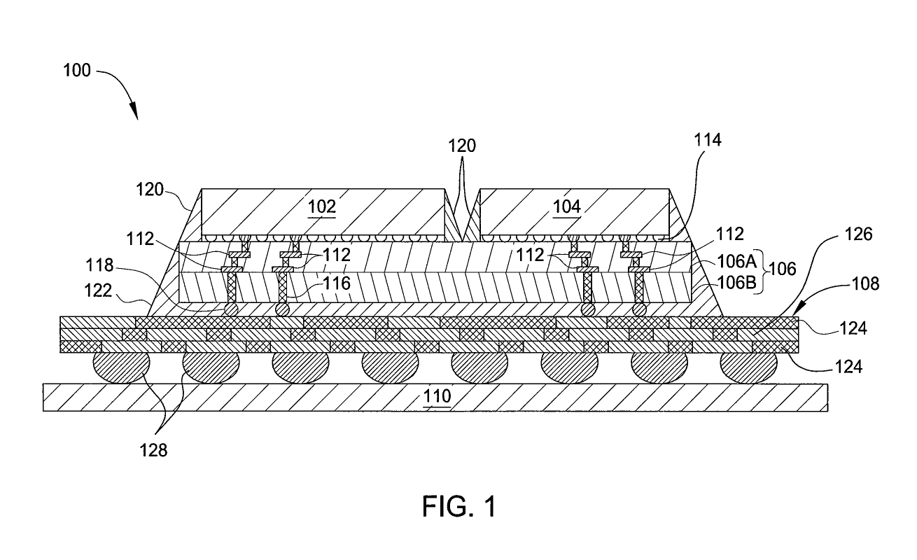

FIG. 1 illustrates a sectional view of a device 100, according to one embodiment of the invention. The device 100 includes dies 102 and 104 disposed on an interposer 106. The interposer 106 is disposed on a package substrate 108, such as a silicon substrate. The package substrate 108, in turn, is disposed on a printed circuit board 110. The dies 102 and 104 are coupled to a redistribution layer 112 disposed on the upper surface of the interposer 106 by microbumps 114. The microbumps 114 include, for example, copper, silver and/or tin, and the redistribution layer 112 generally includes copper or another electrically-conductive material. The microbumps 114 facilitate an electrical connection between the dies 102 and 104, and the redistribution layer 112. While only two dies 102 and 104 are illustrated, it is to be understood that the device 100 may include more than two dies, for example, four, five, or more dies.

A packaging material 120 encapsulates the dies 102 and 104. The packaging material 120 may include, for example, silicone, ultraviolet-curable resins, or epoxies. The dies 102 and 104 are packaged together on the interposer 106, and thus, generally occupy a smaller surface area than if each of the dies 102 and 104 were packaged individually on respective package substrates 108. The utilization of the interposer 106 allows the dies 102 and 104 to be positioned more closely together while being properly packaged in comparison to packaging the dies 102 and 104 separately on distinct packaging substrates 108. For example, when dies are packaged individually, more area is required on a printed circuit board for placement and positioning of the individually packaged dies. Thus, the size and form factor of devices using individually packaged dies is limited. Moreover, placement of the dies 102 and 104 on the interposer 106 simplifies alignment on the printed circuit board 110. Rather than placing and aligning each die 102, 104 on the printed circuit board 110 separately, only placement on the interposer 106 needs to be made (e.g., placement of the interposer 106).

The interposer 106 includes a silicon substrate 106B having vertically-disposed vias 116 therethrough, and a silicon dioxide layer 106A disposed on the silicon substrate 106B. The vias 116 are plated or filled with an electrically conductive material, such as copper, aluminum, or gold, and facilitate electrical connection between the redistribution layers 112 disposed within the silicon dioxide layer 106B and the package substrate 108. It is to be noted that the interposer 106 may include more redistribution layers 112 and vias 116 than are shown. The interposer 106 is coupled to the package substrate 108 using solder bumps 118, which include, for example, tin, gold, copper and/or silver. A gapfill material 122, such as a non-conductive resin, is disposed between the interposer 106 and the package substrate 108 around the solder bumps 118. The gapfill material 122 is utilized to remove air gaps from between the interposer 106 and the package substrate 108 which would otherwise degrade the performance or longevity of the device 100.

The package substrate 108 includes electrically-conductive regions 124 electrically coupled by vias 122. The electrically conductive regions 124 and the vias 122 facilitate electrical contact between the solder bumps 118 and the bumps 128. The bumps 128 are in electrical contact with the printed circuit board 110. The bumps 128 are formed from an electrically conductive material such as tin, copper, or gold.

As illustrated in FIG. 1, multiple dies 102 and 104 can be packaged together on a single package substrate 108 in a substantially coplanar configuration. Because the dies 102 and 104 are packaged together, less printed circuit board area and less packaging substrate area are needed to package the same amount of dies as compared to when the dies are packaged individually. Thus, the device 100 has a small form factor, which facilitates integration into smaller devices, such as smart phones. The packaging of multiple dies on a single package substrate is facilitated by the interposer 106. The interposer 106 provides a mounting surface for the dies in the package. Additionally, the redistribution layers 112 of the interposer 116 provide electrical communication between dies within the package.

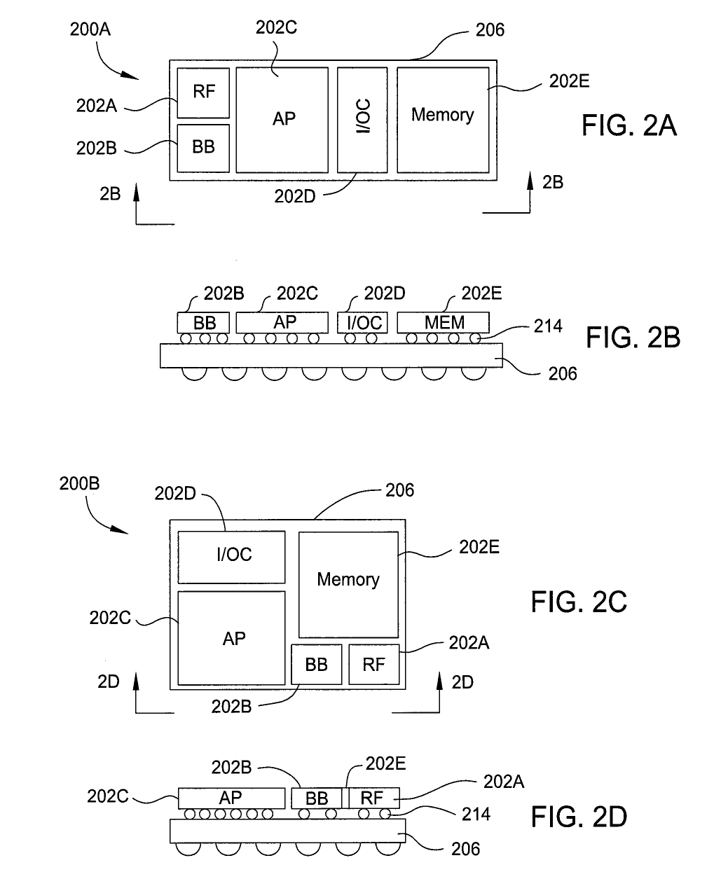

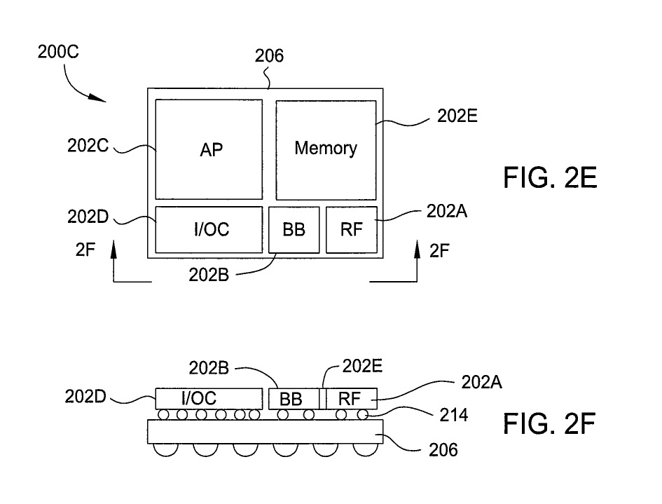

FIGS. 2A-2F illustrate die configurations on passive interposers, according to embodiments of the invention. A passive interposer is an interposer that does not incorporate any electrical die functionality therein. Thus, a passive interposer provides support for dies positioned thereon and facilitates electrical connection between the dies and a package substrate, such as a package substrate 108 shown in FIG. 1.

FIGS. 2A and 2B illustrate respective top and side views of a device 200A. The device 200A includes dies 202A-202E arranged in an elongated pattern on an interposer 206. The dies 202A-202E are coupled to the interposer 206 by microbumps 214. The dies 202A-202E include an RF component, a base band component, an application processor, an I/O controller, and a memory, respectively. The dies 202A-202E are packaged together using the interposer 206 for support and interconnectivity, and thus, require less area on a package substrate and a printed circuit board for final assembly. Although five dies 202E-202E are shown, it is to be understood that more dies may be disposed on the interposer 206.

FIGS. 2C-2F illustrate top and side views of devices 200B and 200C. Each of the devices 200B and 200C have dies 202A-202E disposed on an interposer 206. The five dies are packaged into a single package, and thus, utilize less area when disposed on a printed circuit as compared to when each die 202A-202E is packaged individually. The dies 202A-202E are arranged in two-dimensional patterns on the interposers 206. Thus, it is apparent that the dies 202A-202E can be arranged in multiple patterns within a single package in order to obtain the desired shape or form of the package.

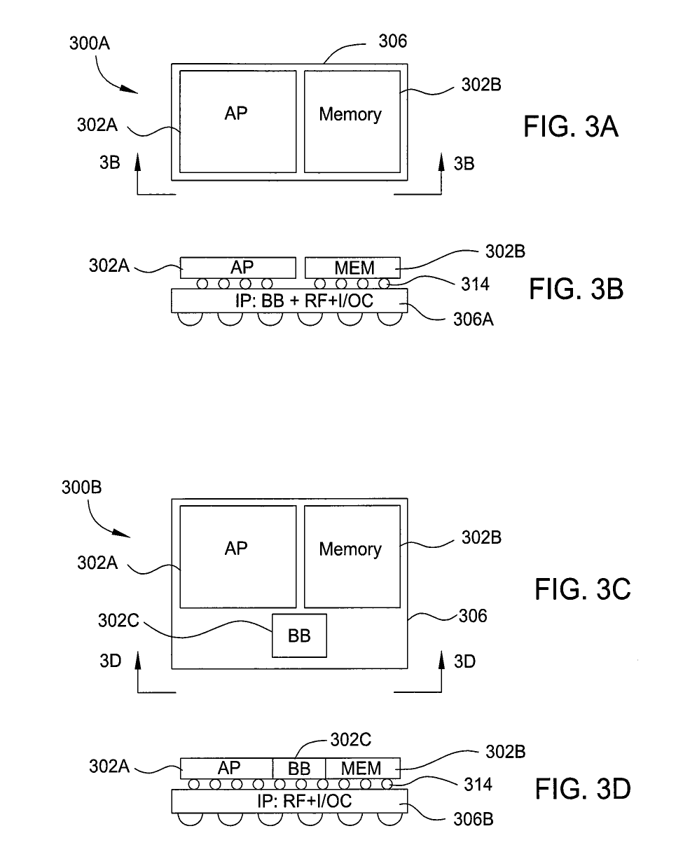

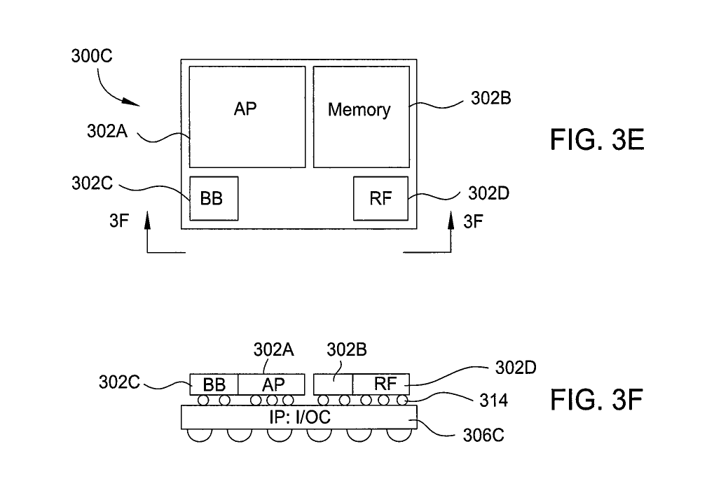

FIGS. 3A-3F illustrate die configurations on active interposers, according to embodiments of the invention. The devices 300A-300C include multiple dies disposed on active interposers 306A-306C for packaging within a single package. The active interposers 306A-306C possess electrical functionality of one or more dies, and thus, reduce the number of dies disposed thereon by incorporating the functionality of dies therein. Because some of the functionality of the dies is incorporated into the interposer 306, the devices 300A-300C have smaller form factors compared to devices using passive interposers 206 (shown in FIG. 2), as well as devices using individually packaged dies.

FIGS. 3A and 3B illustrate respective top and side views of a device 300A having dies 302A and 302B disposed on an active interposer 306A. The dies 302A and 302B are coupled to the active interposer 306A by microbumps 314. The active interposer 306A incorporates the functionality of a baseband component, and RF component, and an I/O controller therein. The die 302A is an application processor, and the die 302B is a memory component. The dies 302A and 302B are packaged into a single package utilizing the interposer 306A. Because the dies 302A and 302B are packaged into a single package, and because the interposer 306A incorporates die functionality therein, the device 300A has a relatively small form factor.

FIGS. 3C and 3D illustrate respective top and side views of a device 300B having dies 302A, 302B, and 302C disposed on an active interposer 306A. The active interposer 306A incorporates the functionality of an RF component and I/O controller therein. Thus, the number of dies disposed on the upper surface of the active interposer 306B is less than the number of dies disposed on a passive interposer for a device having the same functionality. Because the die functionality of an RF component and an I/O controller has been incorporated into the active interposer 306B, and because the dies 302A, 302B, and 302C are packaged together, the area of the device 300B on a printed circuit board is reduced compared to the area of individually packaged dies having the same functionality.

FIGS. 3E and 3F illustrate respective top and side views of a device 300C having dies 302A, 302B, 302C, and 302D disposed on an active interposer 306C. The active interposer 306C incorporates the functionality of an I/O controller therein. Thus, the number of dies disposed on the upper surface of the active interposer 306C is less than the number of dies disposed on a passive interposer for a device having the same functionality. Because the die functionality of an I/O controller has been incorporated into the active interposer 306C, and because the dies 302A, 302B, 302C, and 302D are packaged together, the area of the device 300C on a printed circuit board is reduced compared to the area of individually packaged die having the same functionality.

It is to be noted from FIGS. 3A-3C that the functionality of the active interposer and the number of dies disposed thereon can be varied to obtain the desired form factor of the device. Moreover, the arrangement of the dies thereon can also be varied as desired to further affect the form factor. FIGS. 3A-3C are merely illustrative of some embodiments, and additional variations are contemplated.

The device of the present invention utilizes a TSV interposer upon which multiple dies are interconnected. The TSV interposer having the multiple dies thereon is then disposed on a package substrate that is then positioned on a printed circuit board. The multiple dies are packaged together in a single package on the interposer, rather than each die being packaged separately on a distinct package substrate. The TSV interposer may be passive or active. When the TSV interposer is passive, the TSV interposer does not have any electrical component functionality, and only serves as a substrate to support and interconnect the dies. When the TSV interposer is active, the TSV interposer has at least some electrical component functionality and thus reduces the number of dies on the TSV interposer.

Benefits of the present invention include a smaller form factor for manufactured devices. Because multiple dies with different functions are integrated into a single package, the amount of space required to interconnect the dies is reduced as compared to discretely packaged dies. Additionally, because the device has a smaller form factor, the electrical performance of the device is increased due to shorter electrical paths between the dies. Furthermore, because the multiple dies are packaged in a single package rather than multiple packages, less packaging material is required. Thus, the cost of materials and assembly is reduced. The relatively smaller form factor of the devices of the present invention is desirable for mobile or otherwise compact applications.

While the foregoing is directed to embodiments of the present invention, other and further embodiments of the invention may be devised without departing from the basic scope thereof, and the scope thereof is determined by the claims that follow.

1. An electronic device, comprising:
a package substrate;
an interposer disposed on and electrically coupled to the package substrate, the interposer including a silicon substrate having a silicon dioxide layer disposed thereon; and
a plurality of dies disposed on and electrically coupled to the interposer.

2. The electronic device of claim 1, wherein the plurality of dies are arranged in a substantially coplanar configuration.

3. The electronic device claim of claim 1, further comprising a redistribution layer on an upper surface of the interposer.

4. The electronic device of claim 3, wherein the interposer includes a plurality of vias extending from the upper surface to a lower surface.

5. (canceled)

6. The electronic device of claim 1, wherein the interposer is a passive interposer.

7. The electronic device of claim 6, wherein the plurality of dies includes five dies disposed on a single surface of the interposer.

8. The electronic device of claim 7, wherein the plurality of dies comprise an application processor, a base band component, a memory, an I/O controller, and an RF component.

9. The electronic device of claim 1, wherein the interposer is an active interposer.

10. The electronic device of claim 9, wherein the active interposer includes the functionality of a baseband component, an RF component, and an I/O controller.

11. The electronic device of claim 10, wherein the plurality of dies comprise an application processor and a memory component.

12. The electronic device of claim 9, wherein the active interposer includes the functionality of an RF component and an I/O controller.

13. The electronic device of claim 12, wherein the plurality of dies comprise an application processor, a memory component, and a baseband component.

14. The electronic device of claim 9, wherein the active interposer includes the functionality of an I/O controller.

15. The electronic device of claim 14, wherein the plurality of dies comprise an application processor, a memory component, an RF component, and a baseband component.

16. The electronic device of claim 1, further comprising a printed circuit board coupled to the package substrate.

17. The electronic device of claim 1, further comprising underfill material disposed between the interposer and the package substrate.

18. The electronic device of claim 17, wherein:
the interposer includes a plurality of vias extending from a front surface of the interposer to a back surface of the interposer; and
the package substrate includes a plurality of vias extending from a front surface of the package substrate to a back surface of the package substrate.

19. The electronic device of claim 1, wherein the silicon substrate includes vertically-disposed vias therethrough, and the silicon dioxide layer includes redistribution layers disposed therein.
